(19) United States
(12) Patent Application Publication
(10) Pub. No.: US 2014/0353981 A1
(43) Pub. Date: Dec. 4, 2014

(54) Latch Mechanism

(71) Applicant: Hewlett-Packard Development Company, L.P., Fort Collins, CO (US)

(72) Inventor: Sheng-Kai Su, Taipei (TW)

(21) Appl. No.: 13/905,039

(22) Filed: May 29, 2013

(51) Int. Cl. H05K 5/02

(52) U.S. Cl. CPC H05K 5/0221
USPC 292/195

(57) ABSTRACT

A latch mechanism that includes first and second latch members is described according to one aspect of the present disclosure. The first latch member is connected to a back cover of an electronic device and has an engaging portion. The second latch member is connected to a main casing body of the electronic device and has an engaging segment and a pushing segment. The second latch member is rotatable between a locking position, where the engaging segment engages the engaging portion, and a releasing position, where the engaging segment is disengaged from the engaging portion and the pushing segment pushes the first latch member, thereby facilitating removal of the back cover from the main casing body.

### BACKGROUND

An electronic device, such as a tablet computer, generally includes a casing and a touch screen coupled to a front end of the casing. The casing includes a main casing body, and a back cover coupled to a rear end of the main casing body and removable from the main casing body for facilitating repair or replacement of elements inside the casing. The electronic device is conventionally provided with a plurality of screw fasteners for securing the back cover to the main casing body.

### BRIEF DESCRIPTION OF THE DRAWINGS

Examples are described in the following detailed description and in reference to the drawings, in which:

FIG. 1 is a perspective view of an electronic device mounted with a first embodiment of a latch mechanism according to an aspect of the present disclosure;

FIG. 2 is fragmentary sectional view of the first embodiment, illustrating a second latch member at a locking position according to an aspect of the present disclosure;

FIG. 3 is another fragmentary sectional view of the first embodiment, illustrating the second latch member at a releasing position according to an aspect of the present disclosure;

FIG. 4 is still another fragmentary sectional view of the first embodiment, illustrating operation of the first embodiment when a back cover is coupled to a main casing body according to an aspect of the present disclosure;

FIG. 5 is a fragmentary perspective view of a back cover of the electronic device and two first latch members of a second embodiment of the latch mechanism according to an aspect of the present disclosure;

FIG. 6 is a perspective view of the a second latch member of the second embodiment according to an aspect of the present disclosure;

FIG. 7 is a fragmentary perspective view of a lateral wall of the electronic device and a driving portion of a driving member of the second embodiment according to an aspect of the present disclosure;

FIG. 8 is a fragmentary schematic sectional view of the second embodiment, illustrating engaging segments of the second latch member at inner groove ends of engaging grooves of the first latch members according to an aspect of the present disclosure; and

FIG. 9 is another fragmentary schematic sectional view of the second embodiment, illustrating the engaging segments of the second latch member at outer groove ends of the engaging grooves of the first latch members according to an aspect of the present disclosure.

### DETAILED DESCRIPTION

The present disclosure relates generally to a latch mechanism, and more particularly to a latch mechanism for removing a back cover of an electronic device.

As mentioned above, an electronic device is conventionally provided with a plurality of screw fasteners for securing the back cover to the main casing body. Such screws may extend forwardly through the back cover into the main casing body in order to lock the back cover to the main casing body. The screws, however, are easily seen from the rear of the electronic device, thereby degrading the visual aesthetic appeal of the electronic device.

Therefore, an object of the present disclosure is to provide a latch mechanism for use in an electronic device that can alleviate the aforesaid problems and that is easily operated.

According to an aspect of the present disclosure, there is provided a latch mechanism to use with an electronic device. The electronic device includes a casing that has a main casing body and a back cover coupled removably to the main casing body. The latch mechanism comprises a first latch member, a second latch member and a driving member. The first latch member is connected to the back cover and has an engaging portion. The second latch member is connected movably to the main casing body and has an engaging segment and a pushing segment. The second latch member is rotatable about a rotational axis relative to the first latch member between a locking position, where the engaging segment of the second latch member engages the engaging portion of the first latch member, and a releasing position, where the engaging segment of the second latch member is disengaged from the engaging portion of the first latch member and the pushing segment of the second latch member pushes the first latch member to move in a direction transverse to the rotational axis and away from the second latch member, thereby facilitating removal of the back cover from the main casing body. The driving member extends along the rotational axis and has a driving portion that is connected securely to the second latch member, and an accessible portion that is connected to the driving portion and that is to be exposed from the main casing body. The driving member is rotatable about the rotational axis to drive the rotation of the second latch member.

According to another aspect of the present disclosure, there is provided a latch mechanism for use with an electronic device. The electronic device includes a casing that has a main casing body. The latch mechanism comprises at least one first latch member, a second latch member and a driving member. The first latch member is to be connected to the back cover and that is formed with an engaging groove. The second latch member is to be connected to the main casing body, has at least one engaging segment that engages slidably the engaging groove of the at least one first latch member, and is movable in a driving direction. The engaging groove is inclined with respect to the driving direction. The second latch member is movable in the driving direction relative to the first latch member to push the first latch member to move in a first transverse direction transverse to the driving direction, thereby resulting in removal of the back cover from the main casing body. The driving member extends in the driving direction and has a driving portion that is connected securely to the second latch member, and an accessible portion that is connected to the driving portion and that is adapted to be exposed from the main casing body, the driving member is rotatable to drive the movement of the second latch member.

Before providing greater detail on aspects of the present disclosure, it should be understood that like elements are denoted by the same reference numerals throughout the disclosure.

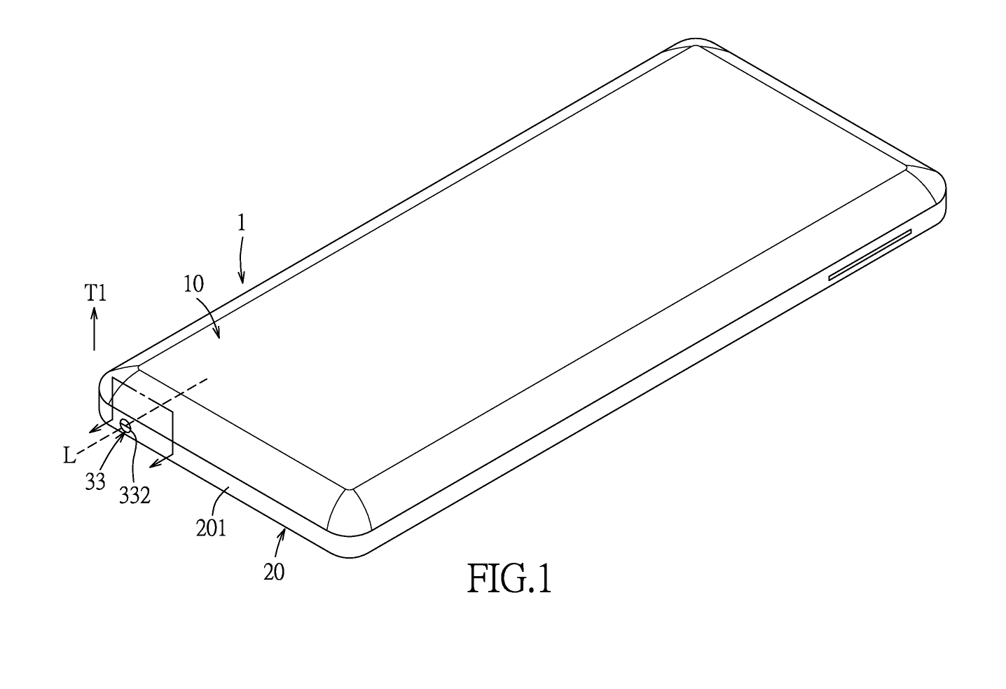

As shown in FIGS. 1 to 4, the first embodiment of a latch mechanism according to the present disclosure is adapted for use with an electronic device 1, such as a tablet computer. The electronic device 1 includes a casing and a touch screen connected to a front end of the casing. The casing includes a main 25 casing body 20 and a back cover 10. A plurality of the latch mechanisms 30 (only one is shown) are provided between the main casing body 20 and the back cover 10 for removably coupling the back cover 10 to a rear end of the main casing body 20. Since the latch mechanisms 30 are identical in construction, only one of them will be described in greater detail hereinafter for the sake of brevity.

The latch mechanism 30 includes a first latch member 31, a second latch member 32 and a driving member 33.

In this embodiment, the first latch member 31 is connected to an inner surface of the back cover 10, and has an engaging portion 311 configured as a recess that is formed in a lateral side of the first latch member 31.

The main casing body 20 has an inner surface provided with a stationary seat 21 that corresponds in position 15 to the first latch member 31. The driving member 33 extends along a rotational axis (L) through a lateral wall 201 of the main casing body 20, and has a driving portion 331 connected securely and rotatably to the stationary seat 21 of the main casing body 20, and an 20 accessible portion 332 connected to the driving portion 331 and exposed from the lateral wall 201 of the main casing body 20.

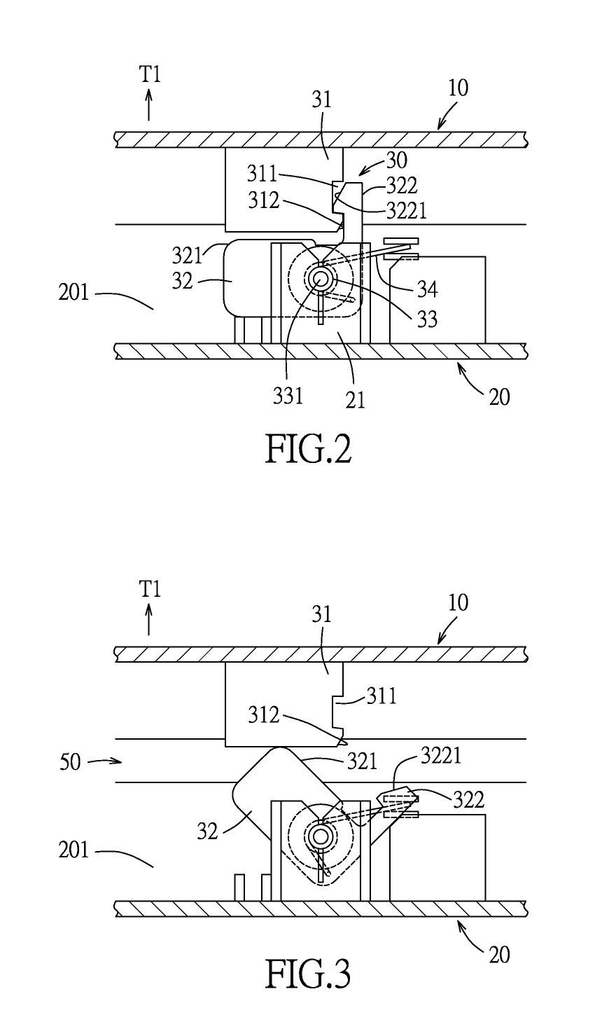

In this embodiment, the second latch member 32 is L-shaped, and has a pushing segment 321 and an engaging segment 322 substantially perpendicular to the pushing segment 321. The second latch member 32 is connected co-rotatably to the driving portion 331 of the driving member 33. The engaging segment 322 is configured as a hook. The second latch member 32 is rotational about the rotational axis (L) relative to the first latch member 31 between a locking position (see FIG. 2), where the engaging segment 322 engages the engaging portion 311 of the first latch member 31 and the pushing segment 321 is away from the engaging portion 311, and a releasing position (see FIG. 3), where the engaging segment 322 is disengaged from the engaging portion 311 and the pushing segment 321 pushes the first latch member 31 to move away from the main casing body 20.

The latch member 30 further includes a resilient member 34 connected to the driving portion 331 of the driving member 33. In this embodiment, the resilient member 34 is configured as a torsion spring for biasing the second latch member 32 toward the locking position.

When the back cover 10 is properly coupled to the main casing body 20, the second latch member 32 is disposed at the locking position. To remove the back cover 10 from the main casing body 20, a user rotates the accessible portion 332 by, for example, a hand tool to rotate the driving member 33 about the rotational axis (L) against a biasing force of the resilient member 34, thereby moving the second latch member 32 from the locking position to the releasing position. Simultaneously, the pushing segment 321 of the second latch member 32 pushes the first latch member 31 to move the first latch member 31 in a first transverse direction (T1) transverse to the rotational axis (L) and away from the second latch member 32, so that the portion of the back cover 10 connected to the first latch member 31 is separated from the main casing body 20. Such separation of the portion of the back cover 10 from the main casing body 20 would result in a gap 50 between the back cover 10 and the main casing body 20 to facilitate removal of the back cover 10 from the main casing body 20, since the gap 50 allows the user to hold the back cover 10 manually to remove the entire back cover 10 from the main casing body 20. Therefore, the back cover 10 can be easily removed from the main casing body 20 via the rotation of the driving member 33. 15 Moreover, since the driving member 33 is provided on the lateral wall 201 of the main casing body 20 instead of the back cover 10, the visual aesthetic appeal of the electronic device 1 when viewed from the back would not be affected. In some examples, the driving member 33 is provided at the lateral wall 201 that is at the lower part of the main casing body 20 when the electronic device is held upright.

In this embodiment, the first latch member 31 further has an inclined first slide surface 312 formed on a distal and thereof. The engaging segment 322 of the second latch member 32 has an inclined second slide surface 3221 formed on a distal end thereof. As shown in FIG. 4, when coupling the back cover 10 to the main casing body 20, the first slide surface 312 is in slidable contact with the second slide surface 3221, and the second latch member 32 is automatically moved by the first latch member 31 toward the releasing position, thereby permitting movement of the first latch member 31 toward the driving member 33 until the first slide surface 312 is separated from the second slide surface 3221 and the second latch member 32 is biased back to the locking position. Therefore, by virtue of the first and second slide surfaces 312, 3221, the back cover 10 can be easily coupled to the main casing body 20 without manipulation of the driving member 33.

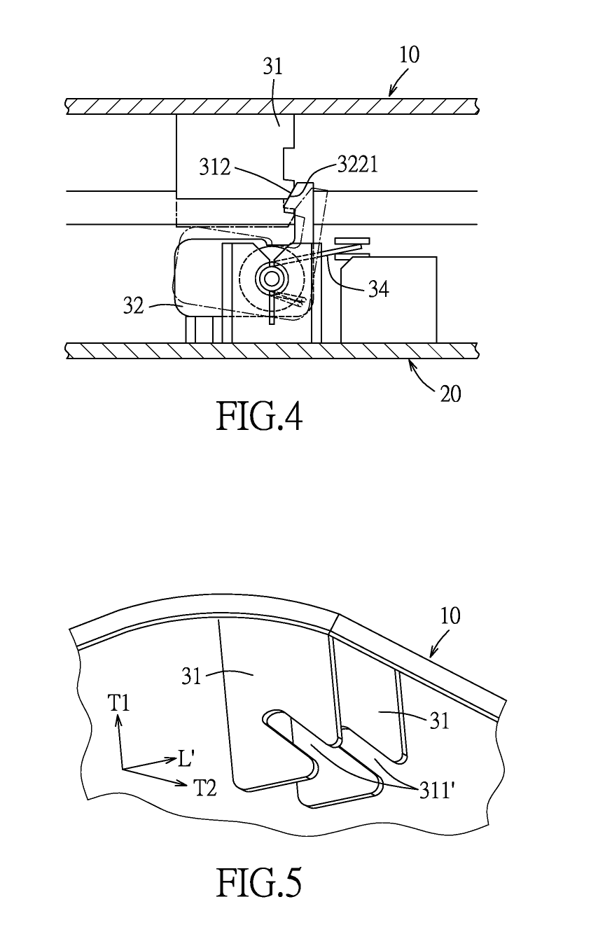

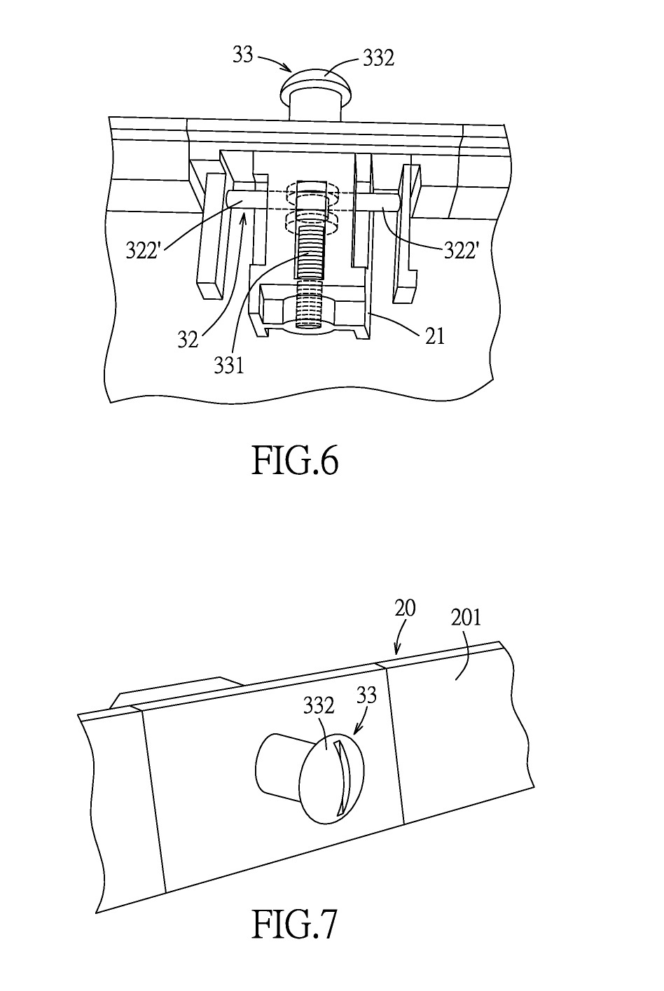

As shown in FIGS. 5 to 9, the second embodiment of a latch mechanism according to the present disclosure has a structure similar to that of the first embodiment. The main difference between this embodiment and the previous embodiment resides in the following.

In this embodiment, the latch mechanism 30 includes a pair of first latch members 31, a second latch member 32 and a driving member 33.

The second latch member 32 is connected to the main casing body 20, and is movable in a driving direction (L′). In this embodiment, the second latch member 32 is configured as a rod extending through the stationary seat 21 in a second transverse direction (T2) transverse to the driving direction (L′) and the first transverse direction (T1), and having two engaging segments 322′ that are disposed at opposite ends thereof and that are exposed from the stationary seat 21.

In this embodiment, the first latch members 31 are aligned with each other in the second transverse direction (T2). Each of the first latch members 31 is configured as a lug extending from the inner surface of the back cover 10 and formed with an engaging groove 311′ that is inclined with respect to the driving direction (L′). The engaging groove 311′ of each of the first latch members 31 has an inner groove end and an outer groove end opposite to the inner groove end and formed at an edge of the first latch member 31. In this embodiment, a distance between the inner groove end and the back cover 10 is shorter than that between the outer groove end and the back cover 10. The engaging grooves 311′ of the first latch members 31 are aligned with each other in the second transverse direction (T2). The engaging segments 322′ of the second latch member 32 engage respectively and slidably the engaging grooves 311′ of the first latch members 31. 25

The driving member 33 extends in the driving direction (L′) and has a driving portion 331 that is connected securely to the second latch member 32, and an accessible portion 332 that is connected to the driving portion 331 and that is exposed from the main casing body 20. The driving portion 331 is connected drivingly to the stationary seat 21, and is rotatable 5 relative to the stationary seat 21 so as to move in the driving direction (L′) relative to the stationary seat 21, thereby resulting in the movement of the second latch member 32 in the driving direction (L′).

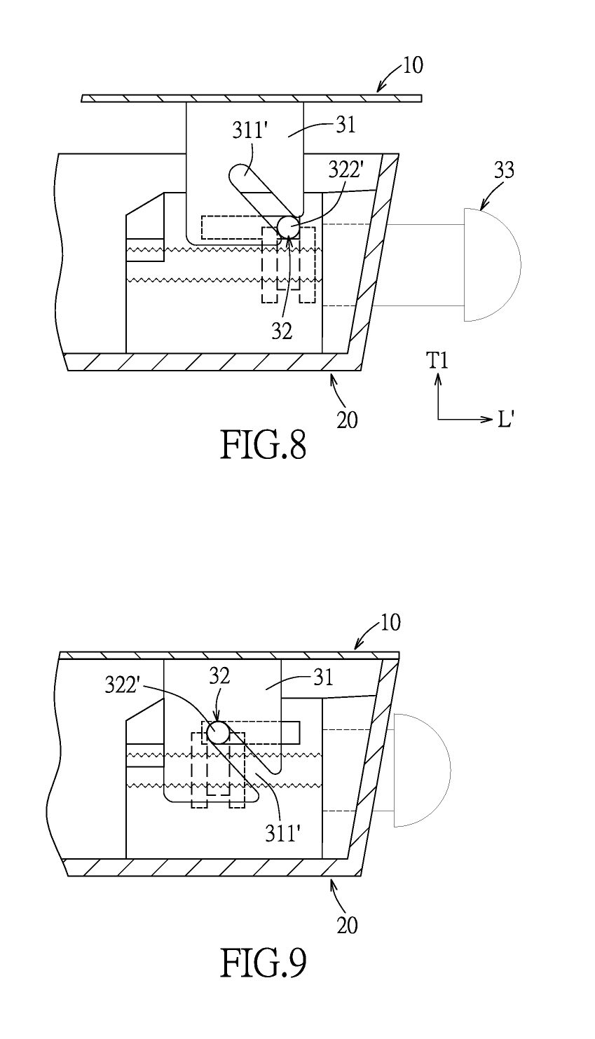

When the back cover 10 is coupled to the main casing body 20, the engaging segments 322′ of the second latch member 32 engage respectively the inner groove ends of the engaging grooves 311′ (see FIG. 9). To remove the back cover 10 from the main casing body 20, the user rotates the driving member 33 to move the driving member 33 away from the lateral wall 201 of the main casing body 20. Since the engaging grooves 311′ are inclined, the movement of the second latch member 32 in the driving direction (L′) would push the first latch members 31 to move in the first transverse direction (T1) while the engaging segments 322′ of the second latch member 32 move from the inner groove ends to the outer groove ends of the engaging grooves 311′ (see FIG. 8), so that the back cover 10 can than be easily removed from the main casing body 20. When coupling the back cover 10 back to the main casing body 20, the engaging segments 322′ of the second latch member 32 are reengaged respectively with the outer groove ends of the engaging grooves 311′, and the driving member 33 is rotated reversely so as to draw the back cover 10 toward the main casing body 20.

While the above disclosure has been shown and described with reference to the foregoing examples, it should be understood that other forms, details, and implementations may be made without departing from the spirit and scope of the disclosure that is defined in the following claims.

What is claimed is:

1. A latch mechanism to use with an electronic device, the electronic device including a casing that has a main casing body and a back cover coupled removably to the main casing body, said latch mechanism comprising:
at least one first latch member connected to the back cover;
a second latch member connected movably to the main casing body; and
a driving member extending in a driving direction and having a driving portion that is connected securely to said second latch member, and an accessible portion that is connected to said driving portion and that is to be exposed from the main casing body, said driving member being operable to move said second latch member relative to said first latch member in a transverse direction that is transverse to the driving direction, thereby resulting in removal of said back cover from the main casing body.

2. The latch mechanism as claimed in claim 1, wherein said accessible portion of said driving member is to be used with a hand tool.

3. A latch mechanism to use with an electronic device, the electronic device including a casing that has a main casing body and a back cover coupled removably to the main casing body, said latch mechanism comprising:
a first latch member connected to the back cover and having an engaging portion;
a second latch member connected movably to the main casing body and having an engaging segment and a pushing segment, said second latch member being rotatable about a rotational axis relative to said first latch member between a locking position, where said engaging segment of said second latch member engages said engaging portion of said first latch member, and a releasing position, where said engaging segment of said second latch member is disengaged from said engaging portion of said first latch member and said pushing segment of said second latch member pushes said first latch member to move in a direction transverse to the rotational axis and away from said second latch member, thereby facilitating removal of the back cover from the main casing body; and
a driving member extending along the rotational axis and having a driving portion that is connected securely to said second latch member, and an accessible portion that is connected to said driving portion and that is to be exposed from the main casing body, said driving member being rotatable about the rotational axis to drive the rotation of said second latch member.

4. The latch mechanism as claimed in claim 3, wherein one of said engaging portion of said first latch member and said engaging segment of said second latch member comprises a hook, and the other one of said engaging portion of said first latch member and said engaging segment of said second latch member comprises a recess.

5. The latch mechanism as claimed in claim 4, wherein said engaging segment of said second latch member comprises a hook, and said engaging portion of said first latch member comprises a recess.

6. The latch mechanism as claimed in claim 5, wherein said second latch member is L-shaped, said engaging segment being perpendicular to said pushing segment.

7. The latch mechanism as claimed in claim 6, wherein said engaging portion is formed in a lateral side of said first latch member.

8. The latch mechanism as claimed in claim 3, wherein said driving member is provided at a lateral wall of said main casing body that is at the lower part of said main casing body.

9. The latch mechanism as claimed in claim 3, further comprising a resilient member connected to said driving portion of said driving member for biasing said second latch member toward the locking position.

10. The latch mechanisms as claimed in claim 9, wherein said resilient member comprises a torsion spring.

11. The latch mechanism as claimed in claim 9, wherein:
said first latch member comprises a first slide surface; and
said engaging segment of said second latch member comprises a second slide surface that is in slidable contact with and is biased by said first slide surface during the coupling of the back cover to the main casing body, such that said second latch member is automatically moved by said first latch member toward the releasing position against the biasing force of said resilient member.

12. The latch mechanism as claimed in claim 3, wherein said accessible portion of said driving member is to be used with a hand tool.

13. A latch mechanism to use with an electronic device, the electronic device including a casing that has a main casing body and a back cover coupled removably to the main casing body, said latch mechanism comprising:
at least one first latch member connected to the back cover and that is formed with an engaging groove;
a second latch member connected to the main casing body, that has at least one engaging segment engaging slidably said engaging groove of said at least one first latch member, and that is movable in a driving direction,
wherein said engaging groove is inclined with respect to the driving direction, and said second latch member is movable in the driving direction relative to said first latch member to push said first latch member to move in a first transverse direction transverse to the driving direction, thereby resulting in removal of the back cover from the main casing body; and
a driving member extending in the driving direction and having a driving portion that is connected securely to said second latch member, and an accessible portion that is connected to said driving portion and that is adapted to be exposed from the main casing body, said driving member being rotatable to drive the movement of said second latch member.

14. The latch mechanism as claimed in claim 13, wherein said driving member is rotatable to move in the driving direction, thereby resulting in the movement of said second latch member in the driving direction.

15. The latch mechanism as claimed in claim 14, wherein:
said engaging groove of said first latch member has an inner groove end and an outer groove end opposite to said inner groove end and formed at an edge of said first latch member, a distance between said inner groove and the back cover being shorter than that between said outer groove end and the back cover;
said engaging segment of said second latch member engage said inner groove and of said engaging groove when the back cover is coupled to the main casing body; and
said engaging segment of said second latch member is moved to said outer groove end of said engaging groove upon removal of the back cover from the main casing body.

16. The latch mechanism as claimed in claim 15, wherein said first latch member comprises a lug extending from an inner surface of the back cover.

17. The latch mechanism as claimed in claim 13, comprising two of said first latch members aligned with each other in a second transverse direction transverse to the driving direction and the first transverse direction, said engaging grooves of said first latch members being aligned with each other in the second transverse direction,
wherein said second latch member comprises a rod extending in the second transverse direction and having two of said engaging segments at opposite ends thereof that engage respectively and slidably said engaging grooves of said first latch members.

18. The latch mechanism as claimed in claim 16, wherein:
said engaging groove of each of said first latch members has an inner groove end and an outer groove end opposite to said inner groove end and formed at an edge of said first latch member, a distance between said inner groove end and the back cover being shorter than that between said outer groove end and the back cover;
said engaging segments of said second latch member engage respectively said inner groove ends of said engaging grooves when the back cover is coupled to the main casing body; and
said engaging segments of said second latch member are moved to said outer groove ends of said engaging grooves upon removal of the back cover from the main casing body.

19. The latch mechanism as claimed in claim 16, wherein each of said first latch members comprises a lug extending from an inner surface of the back cover.

20. The latch mechanism as claimed in claim 13, wherein said accessible portion of said driving member is to be used with a hand tool.
